(19) United States
(12) Patent Application Publication
(10) Pub. No.: US 2005/0116328 A1
(43) Pub. Date: Jun. 2, 2005

(54) Substrate and method of manufacture thereof

(76) Inventors: Kenichi Oi, Osaka (JP); Hirotaka Jiten, Osaka (JP)

Correspondence Address: HARNESS, DICKEY & PIERCE, P.L.C., P.O. BOX 8910, RESTON, VA, 20195, US

(21) Appl. No.: 11/000,038

(22) Filed: Dec. 1, 2004

(30) Foreign Application Priority Data
Dec. 2, 2003 (JP) 2003-403582

(51) Int. Cl. H01L 21/66; G01R 31/26; H01L 21/44; H01L 21/48; H01L 21/50; H01L 23/02

(52) U.S. Cl. 257/678; 438/127

(57) ABSTRACT

A substrate of the present invention includes an electrically-insulating glass layer formed on both sides of a stainless-plate measuring substrate. The substrate also has a wiring pattern on the electrically-insulating glass layer, and an overcoat glass layer covering the wiring pattern. Thus, the present invention provides a substrate that is inexpensive, can withstand a high temperature of about 400° C. in EM evaluations and the like, and can easily be provided in a large size.

This Nonprovisional application claims priority under 35 U.S.C. § 119(a) on Patent Application No. 403582/2003 filed in Japan on Dec. 2, 2003, the entire contents of which are hereby incorporated by reference.

### FIELD OF THE INVENTION

The present invention relates to substrates and methods of manufacture thereof, and in particular, relates to substrates for use under high temperatures and methods of manufacture thereof.

### BACKGROUND OF THE INVENTION

Conventionally, there has been an evaluation testing method of semiconductors, in which testing is carried out by packaging each semiconductor chip that has been cut out of a semiconductor wafer. A problem of this method, however, is that packaging is costly and time-consuming.

Accordingly, disclosed in Japanese Laid-Open Publication No. 329759/2002 (Tokukai 2002-329759; published on Nov. 15, 2002) (Document 1) is a method of checking a semiconductor wafer itself, that is, an evaluation testing method of semiconductors in which an evaluation test signal is sent from a substrate to the pad of each of the dies of a semiconductor wafer as a test piece, with the substrate and the pad in contact with each other.

Meanwhile, in testing semiconductors for evaluation, and more particularly in a reliability evaluation test, EM (electromigration) has been an important test element for evaluating reliability such as life of a semiconductor.

An EM evaluation observes how the electrons flowing through thin wires formed in a semiconductor element push the metal ions toward the positive potential, and how the resulting increase in current density at the holes causes wire breakage. Furthermore, in order to save time, an EM evaluation test is carried out by increasing a current flow through the semiconductor element under high temperatures (200° C. to 400° C.) where metal ions are activated, and changes in wiring resistance over time are measured for evaluation.

Thus, since the EM evaluation is conducted under high temperatures, a substrate is required to be heat resistant in methods in which, as in Document 1, a substrate is connected directly to a semiconductor wafer to send an evaluation test signal. Accordingly, Document 1 discloses a way of forming substrates from ceramic.

Meanwhile, it is generally known that ceramic, such as alumina, and quartz glass can be utilized as materials of heat-resistant substrates capable of withstanding temperatures exceeding 200° C. However, in terms of manufacturing, such a material is expensive since it is not available directly in a plate form, requiring such processes as cutting a big lump thereof into plates and polishing the surface. Particularly, it is difficult to obtain from such a material a large-size substrate that can accommodate a wafer size of 8 inches (200 mm in diameter) or 12 inches (300 mm in diameter). Even if such a substrate is obtained at all, it will be very expensive.

In addition, a plate of ceramic or plate of quartz glass has a drawback of being fragile.

Accordingly, in order to overcome the problem of fragility, there has been proposed ceramic-coated plates prepared by coating metal plates such as stainless steel plates with ceramic. In this case, there is a need for coating ceramic by way of flame spraying and the like after coating the surface of the metal plate with a material for reducing the difference between the coefficients of thermal expansion of the ceramic and the metal plate. There is also a need for polishing and smoothing the surface, making the product substrate very expensive.

### SUMMARY OF THE INVENTION

It is an object of the present invention to provide a substrate that is inexpensive, can withstand a high temperature of about 400° C. in EM evaluations and the like, and can readily be provided in a large size. The present invention also provides a manufacturing method of such a substrate.

In order to achieve the above-mentioned object and obtain a substrate that can be manufactured inexpensively and can withstand 400° C. or higher temperatures, the inventors studied diligently ways to put the substrate to practical use, paying attention to the technique of insulating a surface of a metal plate utilized for plate heaters and the like with a glass coating whose coefficient of thermal expansion is close to that of the metal plate, and printing a heater wiring pattern on the surface of the glass coating.

That is, in order to solve the above-mentioned problems, a substrate of the present invention is provided with an electrically-insulating glass layer on both sides of a steel plate, and a wiring pattern formed on the electrically-insulating layer.

With the above-mentioned structure in which the electrically-insulating glass layer is formed on both sides of the steel plate, and the wiring pattern is formed on the electrically-insulating glass layer, the substrate can withstand temperatures higher than 400° C. and can be manufactured inexpensively.

That is, steel plates can be processed easier than a lump of ceramic, and are strong and not fragile like ceramic plates. Therefore, it is easy to manufacture substrates of a desired size or, for example, large-sized substrates that can accommodate semiconductor wafers with a diameter of 200 mm or 300 mm.

Thus, since steel plates can be processed easily, it is possible to inexpensively provide steel plate substrates.

Moreover, since the electrically-insulating layer formed on the surface of the steel plate is made of glass, the surface of the electrically-insulating layer is smooth immediately after it is formed, making it possible to omit the conventional step of polishing the surface of the electrically-insulating layer, which is required when the electrically-insulating layer is formed by flame spraying ceramic onto the steel plate. This reduces manufacturing costs and thereby allows to provide the substrate even less expensively.

For a fuller understanding of the nature and advantages of the invention, reference should be made to the ensuing detailed description taken in conjunction with the accompanying drawings.

### BRIEF DESCRIPTION OF THE DRAWINGS

FIG. 1 is a schematic plan view of a substrate according to one embodiment of the present invention.

FIG. 2 is a cross-sectional view of the substrate shown in FIG. 1 taken along the line A-A FIG. 3 is a schematic diagram showing a main portion of a semiconductor-testing device using the substrate of FIG. 1 as a semiconductor-wafer measuring substrate.

FIG. 4 is a schematic diagram of a main portion of the measuring substrate shown in FIG. 1 with a semiconductor wafer mounted thereon.

FIG. 5(a) is a plan view of a wafer holder.

FIG. 5(b) is a side view of FIG. 5(a).

FIG. 5(c) is a side view of FIG. 5(a).

FIG. 6(a) is a plan view of a cover.

FIG. 6(b) is a side view of FIG. 6(a).

FIG. 6(c) is a side view of FIG. 6(a).

FIG. 7 is a schematic diagram of a main portion of the semiconductor-testing device with measuring substrates set in a multistage manner, according to another embodiment of the present invention.

### DESCRIPTION OF THE EMBODIMENTS

### First Embodiment

An embodiment of the present invention will be described below. It is to be noted that this embodiment will be described through an example in which a substrate of the present invention is used as a measuring substrate for use in evaluating a semiconductor wafer as a test piece.

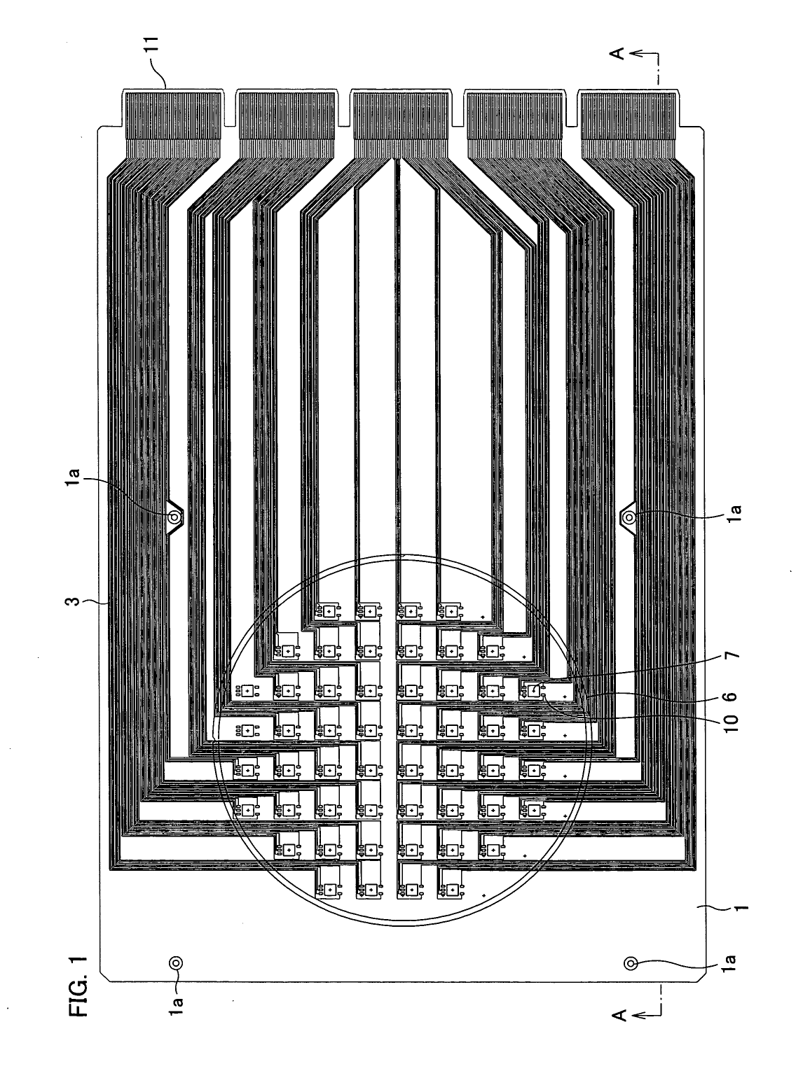

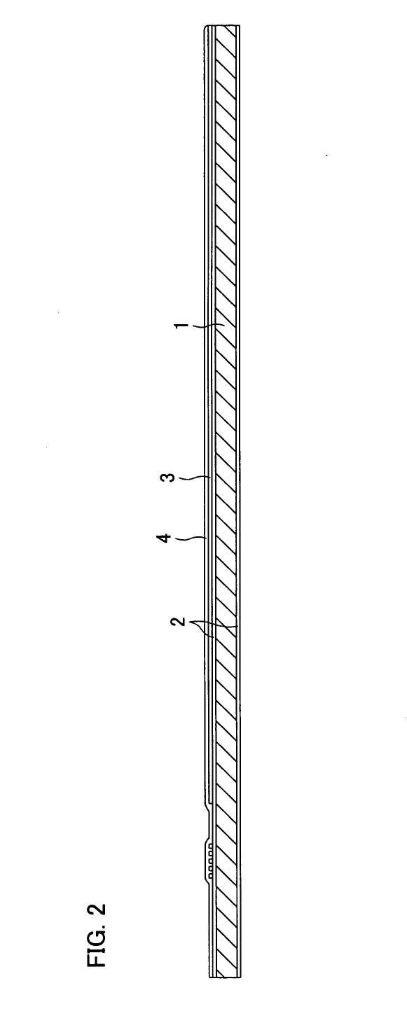

First, a measuring substrate 1 is described in reference to FIGS. 1 and 2. FIG. 1 is a plan view of a measuring substrate 1; FIG. 2 is a cross-sectional view of the measuring substrate shown in FIG. 1 taken along the line A-A.

As shown in FIGS. 1 and 2, the measuring substrate 1 is formed of an oblong steel plate, both sides of the measuring substrate 1 having a vitreous electrically-insulating layer 2, and one side of the measuring substrate 1 having a wiring pattern 3 thereon and further having an overcoat layer 4 for protecting the wiring pattern 3.

In the first step, a paste that vitrifies after calcination is applied by screen printing over the entire area on both sides of a 1.5-mm-thick metal plate (stainless steel SUS430) that has been prepared by cutting a metal plate into a predetermined shape as the measuring substrate 1, and the metal plate is calcinated at about 850° C. to form a 30-μm-thick electrically-insulating layer 2. In the second step, a wiring pattern 3 to be a wiring circuit is screen printed on the surface of the electrically-insulating layer 2 (the upper surface in the calcination) by using a metal paste, and is calcinated in the same way as above to form a metal wiring circuit. In the third step, a 30-μm-thick overcoat (overcoat layer 4) made of the same vitreous material as the electrically-insulating layer 2 is applied to substantially the whole area of the metal wiring pattern except for portions necessary for external connections, so as to protect the metal wiring pattern.

It is preferable here that metals akin to pure silver be used to form the wiring pattern 3 provided as a metal wiring circuit. However, metals used to form the wiring pattern 3 are not to be limited to those akin to pure silver; for example, copper and the like may be used.

Furthermore, silver is employed as a metal for forming the wiring pattern 3 because silver makes it possible to form the wiring pattern 3 inexpensively. Another reason is that silver allows the wiring pattern 3 to be used repeatedly or over an extended period of time. This is due to the strong antioxidative property of silver, which, unlike copper, prevents oxidation that can cause wire breakage over time, even though the pattern surface is oxidized and discolored at a high temperature of 400° C.

In addition, the electrically-insulating layer 2 is made of glass whose coefficient of thermal expansion is close to that of the steel plate of the measuring substrate 1. This prevents the electrically-insulating layer 2 from being detached from the measuring substrate 1 under high temperatures. Note that, although it is preferable that the electrically-insulating layer 2 and the measuring substrate 1 have the same coefficient of thermal expansion, a similar effect can be obtained when they have coefficients of thermal expansion close to each other.

In this embodiment, the measuring substrate 1 is used as a measuring substrate for use in evaluation tests of semiconductor wafers.

Accordingly, as shown in FIG. 1, a mount part 6 for the semiconductor wafer 5 to be tested on the measuring substrate 1 has a multiplicity of holes (through holes) 7 for the bonding wires aligned to the die layout of the semiconductor wafer 5. That is, the holes 7 are provided to expose pads necessary for the evaluation test of each of the dies of the semiconductor wafer 5.

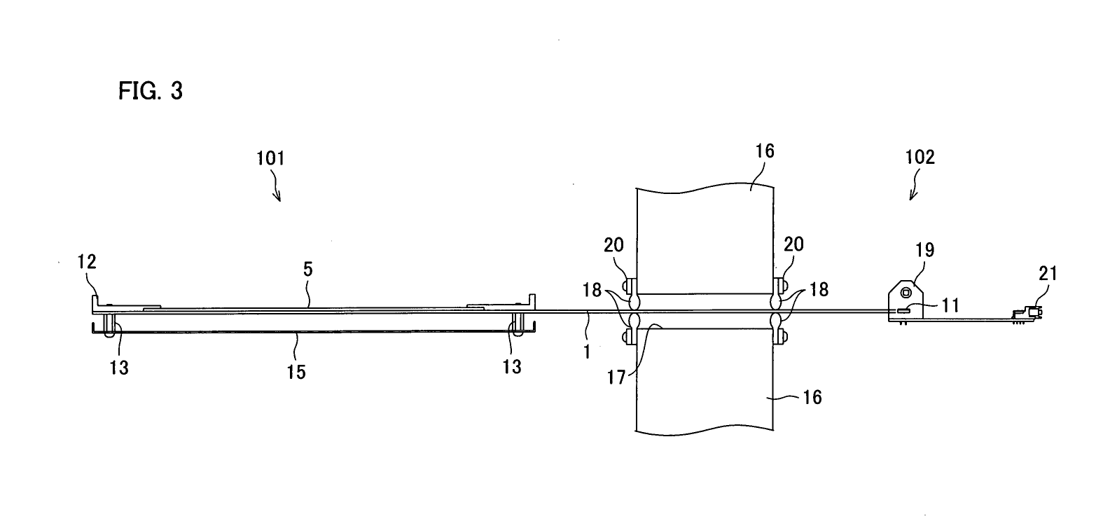

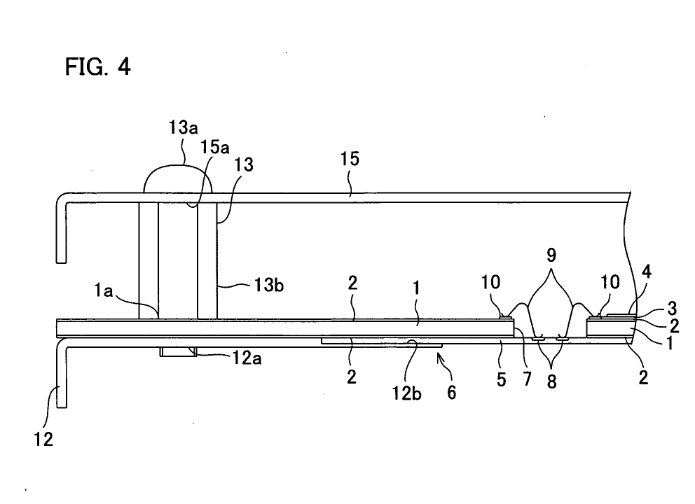

Therefore, as shown in FIG. 4, the bonding pads 8 of the semiconductor wafer 5 are exposed inside of the wiring holes 7, and surrounding each wiring hole 7 are five substrate-side bonding pads 10 for making bonding interconnections with aluminum wires 9.

Four of the five substrate-side bonding pads 10 are four-wire measuring terminals for accurately measuring the electric resistance of the thin wiring of the evaluation element (not shown) formed on the semiconductor wafer 5. The remaining one is a terminal for measuring electric leakage inside the evaluation element. The wiring pattern 3 is delineated from each of the five terminals to the terminal 11 that is to be connected to a measuring instrument (not shown).

As the substrate-side bonding pads 10, gold pads are used because the wiring pattern 3, when made of silver, is hard to connect to the aluminum wires 9 directly.

Furthermore, in the substrate-side bonding pads 10, the connection area for the aluminum wires 9 is two or more times larger than the connection area of the aluminum wire 9, allowing at least one aluminum wire 9 to be connected when the semiconductor wafer 5 being wire bonded for the evaluation test is removed after the evaluation test. This makes it possible to repeat evaluation tests of semiconductor wafers 5 with one measuring substrate 1. For example, making the connection area of the substrate-side bonding pads 10 to aluminum wires 9 three or four times larger than the area of the connection portion of the aluminum wires 9 makes it possible to conduct an evaluation test on three or four semiconductor wafers 5 with one measuring substrate 1.

Thus, since one measuring substrate 1 can repeat evaluation tests of semiconductor wafers 5, evaluation tests of semiconductor wafers 5 can be conducted inexpensively.

The measuring substrate 1 is provided with holes 1a at four corners around the mount part 6 of the semiconductor wafer 5. The holes 1a are to fix the wafer holder 12 and the cover 15, as will be described later.

A semiconductor-testing device using the above-mentioned measuring substrate 1 will be described below.

A semiconductor-testing device is a device that, with a semiconductor wafer mounted on a measuring substrate 1, conducts an evaluation test on the semiconductor wafer by applying an evaluation test signal on the semiconductor wafer 5 through the measuring substrate 1. For example, as shown in FIG. 3, the semiconductor-testing device conducts various types of evaluation tests with a semiconductor wafer 5 mounted on a measuring substrate 1.

As shown in FIG. 3, the semiconductor-testing device includes a high temperature chamber 101 for setting the temperature of the semiconductor wafer 5 as required for an evaluation test of the semiconductor wafer 5, and a signaling chamber 102 for supplying an evaluation test signal to be applied to the semiconductor wafer 5.

The high temperature chamber 101 is able to keep heating the semiconductor wafer 5 according to evaluation tests of semiconductors. The present embodiment assumes an EM evaluation, in which a semiconductor wafer 5 needs to be heated up to about 400° C.

In addition, the signaling chamber 102 is provided with a connector 19, to which a terminal 11 (a terminal that is connected to a wiring pattern 3 to be described later) on the edge of the measuring substrate 1 is connected. The connector 19 is provided with a terminal 21 that is connected to a measuring instrument (not shown).

Therefore, since the signaling chamber 102 is, as mentioned above, provided with means (a measuring instrument and the like) by which an evaluation test signal is sent to the semiconductor wafer 5, it needs to avoid the high temperature of the high temperature chamber 101.

Accordingly, in this embodiment, a heat-insulating wall 16 is, as shown in FIG. 3, provided between the high temperature chamber 101 and the signaling chamber 102, so that the heat of the high temperature chamber 101 does not easily transfer to the signaling chamber 102. This makes it possible to keep the inside temperature of the signaling chamber 102 lower than that of the high temperature chamber 101.

The heat-insulating wall 16 is provided with a hole 17 for the measuring substrate 1 to pass through. The hole 17 is equipped with flexible materials 18 serving as heat-insulating members. The flexible materials 18 are provided at the both ends of the hole 17 meeting the high temperature chamber 101 and the signaling chamber 102, and are tightly in contact with both surfaces of the measuring substrate 1. The flexible materials 18 are formed of a bundle of fiberglass and the like for example, and are fastened on the surface of the heat-insulating wall 16 with screws 20.

Thus, providing the flexible materials 18 at the openings of the hole 17 makes it possible to maintain the heat insulation effect when the measuring substrate 1 is set in the semiconductor-testing device.

Thus, by the provision of the heat-insulating wall 16 between the high temperature chamber 101 and the signaling chamber 102, the high temperature of the high temperature chamber 101 can be maintained for accurate testing. In addition, the signaling chamber 102, i.e., exterior of the hole 17, is provided with a connector 19, which is to be connected to a measuring instrument (not shown). The connector 19 and the terminal 11 interdigitate to electrically connect an evaluation element of the semiconductor wafer 5 to the measuring instrument, so that testing may be conducted. The signaling chamber 102 needs to be kept away from high temperature. Enhancing airtightness as above by providing the flexible materials 18 at the respective openings of the hole 17 lowers heat transfer from the high temperature chamber 101 to the signaling chamber 102.

Moreover, in this embodiment, in order to enhance the cooling effect in the signaling chamber 102, a ventilator (not shown) is provided for ventilating a portion of the measuring substrate 1 exposed outside the high temperature chamber 101, i.e., a portion exposed inside the signaling chamber 102.

Note that, since it is the high temperature chamber 101 that needs to be heated, the signaling chamber 102 does not need to be treated as a chamber. In fact, a corresponding part of the signaling chamber 102 may be left open.

That is, the signaling chamber 102 does not need to be a chamber since the measuring substrate 1 only needs to set the semiconductor wafer 5 inside the high temperature chamber 101, and the terminal part for applying an evaluation test signal outside the high temperature chamber 101.

The wafer holder 12 is, as shown in FIG. 4, an auxiliary member for mounting and anchoring the semiconductor wafer 5 in a predetermined place (mount part 6) of the measuring substrate 1, and is used by being bolted to the back of the measuring substrate 1 (the side without the wiring pattern 3) with a male-female stud bolt 13.

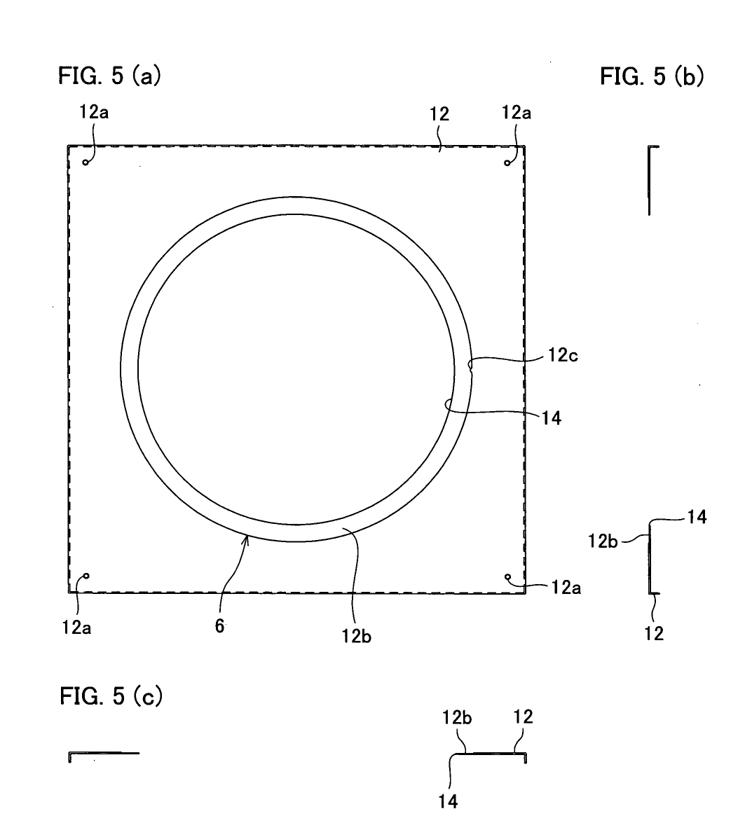

As shown in FIG. 5(a), the wafer holder 12, in the center thereof, has an aperture 14 slightly smaller in outer diameter than the semiconductor wafer 5. The wafer holder 12 also has a step 12b, concentric to the aperture 14, equal in diameter to the semiconductor wafer 5, and equivalent in depth to the thickness of the semiconductor wafer 5. The step 12b is formed by etching the surface of the wafer holder 12 in contact with the back of the measuring substrate 1.

In addition, at four corners around the aperture 14 in the wafer holder 12, holes 12a are provided in the same position as the holes 1a in the measuring substrate 1.

The semiconductor wafer 5 is anchored on the mount part 6 by bolting the male-female stud bolt 13 to the measuring substrate 1 through the holes 1a in the measuring substrate 1 and then through the hole 12a in the wafer holder 12, so that the back of the measuring substrate 1 and the surface of the semiconductor wafer 5 (the side with an evaluation element) are in contact with each other with the semiconductor wafer 5 housed in the step 12b of the wafer holder 12. Moreover, the wafer holder 12 is provided with a notch 12c for preventing the semiconductor wafer 5, when mounted, from rotating in the mount part 6. The notch 12c is to engage a cut-out portion (not shown) of the semiconductor wafer 5.

In addition, as shown in FIGS. 5(b) and 5(c), the four sides of the wafer holder 12 are bent for reinforcement.

Further, in order to anchor the semiconductor wafer 5 on a wire bonder in a later step of bonding wiring, the semiconductor wafer 5 is vacuum-chucked through the hole 14.

Note that, although FIG. 5(a) in this embodiment shows that the wafer holder 12 has its profile center corresponding to the center of the aperture 14, one type of measuring substrate 1 can be used for plural types of semiconductor wafers having various die layouts by moving the position of the aperture 14 according to the die layout of the semiconductor wafer 5.

In addition, as shown in FIG. 3, the cover 15 is provided on the opposite side of the measuring substrate 1 from the semiconductor wafer 5.

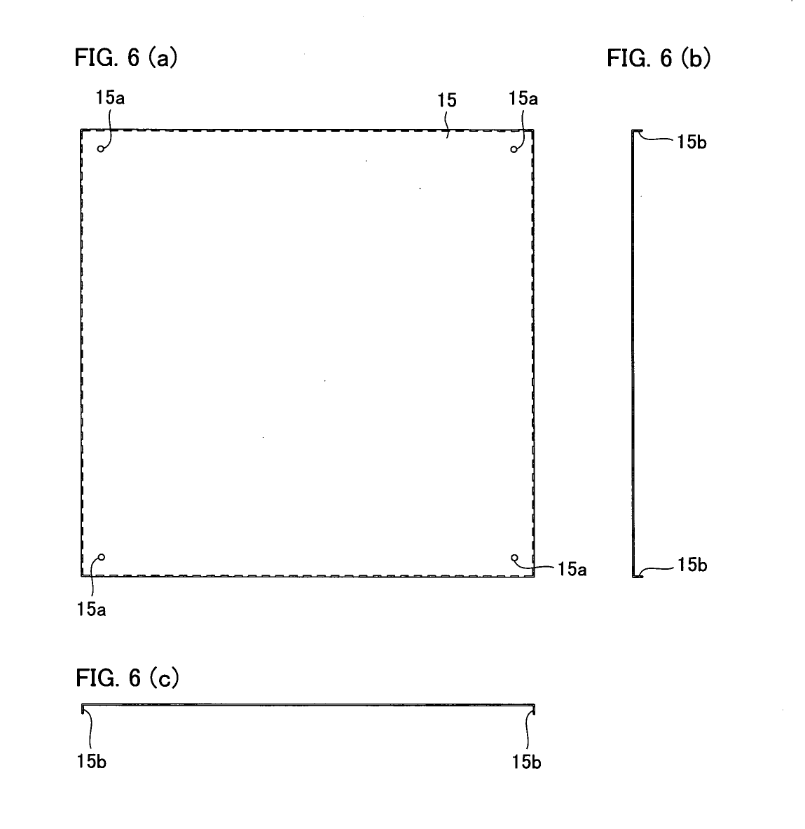

As shown in FIG. 6(a), the cover 15 has holes 15a in four corners thereof. The cover 15 is placed over the surface of the measuring substrate 1 (the side with the wiring pattern 3) and fixed with the female screw 13a of the male-female stud bolt 13, so as to cover the entire area of the wafer mount part 6 of the measuring substrate 1. The cover 15 is used for protecting the bonding wires and preventing accumulation of dust and the like in handling the measuring substrate 1 finished with bonding wiring.

In addition, as is the case with the wafer holder 12, the cover 15 is also made of stainless steel and, as shown in FIGS. 6(b) and 6(c), has its four corners bent for reinforcement.

In the following, a semiconductor-testing method using a semiconductor-testing device of the above-mentioned structure will be described.

Specifically, the following will describe a semiconductor-testing method that, with the semiconductor wafer 5 mounted as a test piece on the measuring substrate 1, conducts an evaluation test by applying an evaluation test signal on the semiconductor wafer 5 through the measuring substrate 1. An evaluation test can be conducted both suitably and inexpensively by carrying out the following steps.

It is to be noted that the measuring substrate 1 is set substantially horizontally in the high temperature chamber 101.

First, in the first step, the semiconductor wafer 5 is mounted, using the wafer holder 12, on the opposite side of the measuring substrate 1 from the wiring pattern 3. Here, the holes 12a of the wafer holder 12 and the holes 1a of the measuring substrate 1 are aligned respectively with each other, and are bolted together with the male screw 13b of the male-female stud bolt 13.

Next, in the second step, the bonding pads 10 of the wiring pattern 3 on the measuring substrate 1 and the bonding pads 8 of the semiconductor wafer 5 are wire bonded with aluminum wires 9.

Then, the cover 15 is placed over the surface of the measuring substrate 1 provided with the wiring pattern 3, where the aluminum wires 9 are exposed. Here, the holes 15a in the cover 15 and the male screws 13b of the male-female stud bolts 13 bolted in the holes 1a in the measuring substrate 1 are aligned with each other and then bolted together with the female screw 13a.

Thereafter, in the third step, as shown in FIG. 3, the measuring substrate 1 with the semiconductor wafer 5 thereon is set in the high temperature chamber 101 with the semiconductor wafer 5 side facing up. The terminal 11 of the measuring substrate 1 interdigitates the connector 19 to electrically connect the evaluation element of the semiconductor wafer 5 to a measuring instrument.

Finally, in the fourth step, a signal according to a semiconductor test is applied to the semiconductor wafer 5, and the high temperature chamber 101 is heated up to a test temperature (400° C.).

The measuring substrate 1 so prepared in the foregoing steps is placed and set in the high temperature chamber 101 upside down. That is, the measuring substrate 1 is set with the semiconductor wafer 5 side facing up.

The first purpose of placing the measuring substrate 1 in the high temperature chamber 101 upside down is to prevent adverse effects of dust on test results. For example, accurate test results cannot be obtained when carbonized dust (conductive) and the like generated by the heat of testing deposits and adheres to exposed parts of the measuring substrate 1 or the semiconductor wafer 5, such as the bonding pads and bonding wires.

The second purpose is to ensure that the semiconductor wafer 5 is tightly in contact with the measuring substrate 1 with its own weight, enabling accurate testing. This is important in consideration of deformation of the wafer holder 12 supporting the semiconductor wafer 5, caused for example by thermal expansion. For example, when heat is applied with the semiconductor wafer 5 side of the measuring substrate 1 facing down, the wafer holder 12 may be deformed and the semiconductor wafer 5 may move out of position on the measuring substrate 1. When the semiconductor wafer 5 moves out of position on the measuring substrate 1, the aluminum wires 9 may be broken, with the result that accurate testing cannot be carried out.

As described above, in the semiconductor-testing device according to this embodiment, the terminal part for applying an evaluation test signal is located outside the high temperature chamber 101 and therefore will not be exposed to such a high temperature of 400° C., for example, even in an evaluation method such as EM evaluation in which a semiconductor wafer needs to be heated to about 400° C.

Furthermore, since the measuring substrate 1 is realized by a substantially oblong metal plate whose surface is coated with an insulating film capable of withstanding temperatures required for the evaluation test, it is no longer necessary to use a conventional expensive ceramic substrate. As a result, an inexpensive evaluation device, i.e., semiconductor-testing device can be provided.

Although, in this embodiment, the wafer holder 12 is etched so that the semiconductor wafer 5 may be mounted thereon, etching may be carried out on the side of the measuring substrate 1 where the semiconductor wafer 5 is mounted.

In addition, an overcoat glass layer is formed to cover and protect the wiring pattern 3. Particularly, when the wiring pattern 3 is made of metal, the overcoat glass layer can prevent the wiring pattern 3 from being oxidized under high temperatures.

In addition, the electrically-insulating layer 2 has the same coefficient of thermal expansion as the steel plate, so that the steel plate and the electrically-insulating layer 2 made of glass do not easily split even under high temperatures. Furthermore, although it is preferable that the electrically-insulating layer 2 has the same coefficient of thermal expansion as the steel plate, a sufficient effect can be obtained when their coefficients of thermal expansion are substantially the same.

Such a substrate is effective in conducting an evaluation test by mounting the semiconductor wafer 5 directly on the measuring substrate in a semiconductor-testing device.

The wiring pattern 3 has bonding pads for wire bonding to the semiconductor wafer 5. This enables the substrate to be wire bonded with the semiconductor wafer 5. That is, the substrate can be used as an evaluation substrate for evaluating the semiconductor wafer 5.

The bonding pads are formed of gold pads to ensure connection to the aluminum wires generally used as bonding wires.

In the bonding pads, the connection area for the bonding wires is two or more times larger than the connection area of the bonding wires, allowing at least one bonding wire to be connected even when the semiconductor wafer 5 being wire bonded for evaluation test is removed after the evaluation test. This makes it possible to repeat evaluation tests of semiconductor wafers 5 with one substrate. For example, making the connection area of the bonding pad for the bonding wire three or four times larger than the area of the connection portion of the bonding wire makes it possible to conduct an evaluation test on three or four semiconductor wafers with one substrate.

Furthermore, bonding pads need to be so sized as not to touch each other.

Thus, since one substrate can repeat evaluation tests of semiconductor wafers 5, evaluation tests of semiconductor wafers 5 can be conducted inexpensively.

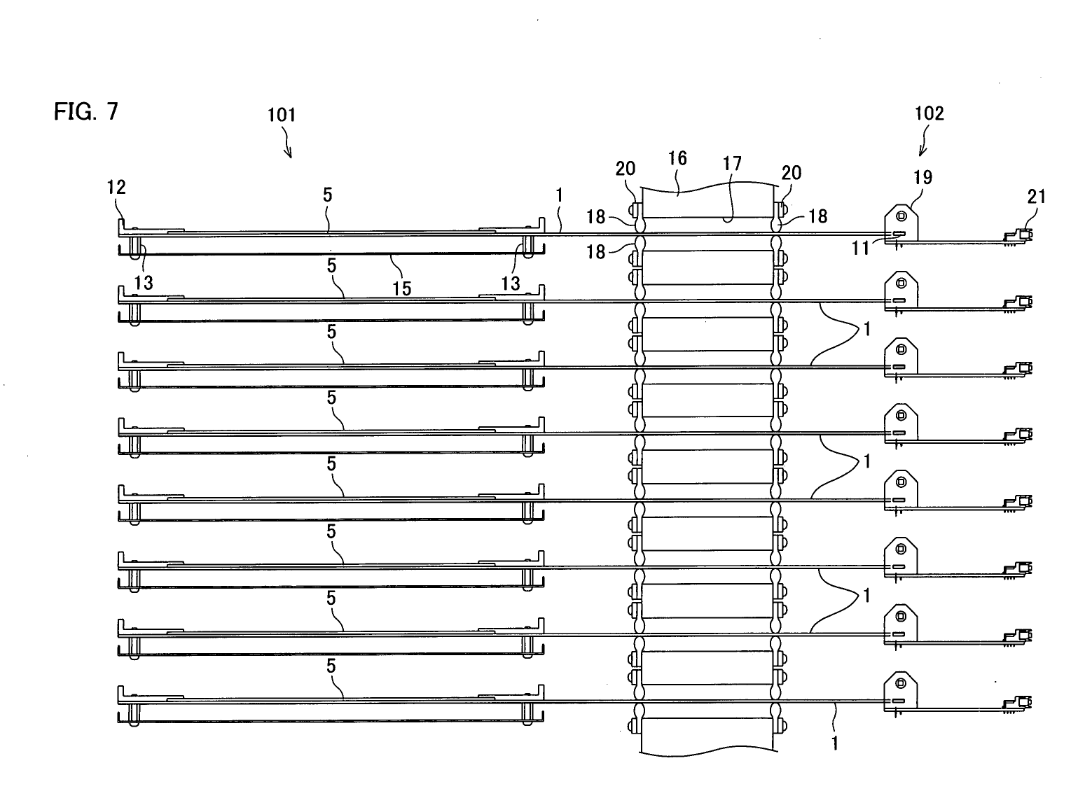

Note that, although this embodiment described the case in which one measuring substrate 1 with the semiconductor wafer 5 is set in the semiconductor device as illustrated in FIG. 3, the present invention is not limited by the described embodiment. For example, as shown in FIG. 7, a measuring substrate 1 may be set in a multistage manner.

By thus setting a plurality of measuring substrates 1 in a multistage manner in the high temperature chamber 101, a large number of semiconductor wafers 5 can be tested simultaneously. In this case, by sending the same evaluation test signal to all the semiconductor wafers 5, identical evaluation tests can be conducted simultaneously on a large number of semiconductor wafers 5. Similarly, by sending different evaluation test signals to the semiconductor wafers 5, different evaluation tests can be conducted simultaneously on a large number of semiconductor wafers 5.

A substrate of the present invention is suitably used under high temperatures, and particularly suitable in an evaluation test that is conducted under high temperatures, such as an EM evaluation, which is one type of evaluation tests of semiconductors. In addition, the substrate is heat resistant enough to be suitably used in other high temperature conditions, for example, as in the field of heating machines such as heaters.

The invention being thus described, it will be obvious that the same way may be varied in many ways. Such variations are not to be regarded as a departure from the spirit and scope of the invention, and all such modifications as would be obvious to one skilled in the art are intended to be included within the scope of the following claims.

1. A substrate comprising:
a steel plate;
an electrically-insulating layer made of glass, formed on both sides of the steel plate; and
a wiring pattern formed on the electrically-insulating layer.

2. A substrate according to claim 1, wherein an overcoat glass layer is formed to cover the wiring pattern.

3. A substrate according to claim 1, wherein the electrically-insulating layer has a coefficient of thermal expansion equal to a coefficient of thermal expansion of the steel plate.

4. A substrate according to claim 1, wherein the wiring pattern has a bonding pad for wire bonding a semiconductor wafer.

5. A substrate according to claim 4, wherein the bonding pad is made of gold.

6. A substrate according to claim 4, wherein the bonding pad has a bonding-wire contact area two or more times larger than a contact area of a connection portion of the bonding wire.

7. A method for manufacturing a substrate, comprising the steps of:
forming an electrically-insulating layer by applying a paste, which vitrifies after calcination, to entire surfaces on both sides of a steel plate, and calcinating the steel plate with the paste applied thereon; and
forming a metal wiring circuit by calcinating the electrically-insulating layer, after a wiring pattern to be a wiring circuit is screen printed on a surface of the electrically-insulating layer using a metal paste.

8. A method for manufacturing a substrate according to claim 7, further comprising the step of forming an overcoat layer by applying a paste, which vitrifies after calcinations, over a substantially entire surface of the metal wiring circuit except for a portion required for external connection, and calcinating the metal wiring circuit with the paste applied thereon.

9. A method for manufacturing a substrate according to claim 7, wherein the electrically-insulating layer has a coefficient of thermal expansion equal to a coefficient of thermal expansion of the steel plate.

10. A method for manufacturing a substrate according to claim 7, further comprising the step of forming, on the wiring pattern, a bonding pad for wire bonding a semiconductor wafer.

11. A method for manufacturing a substrate according to claim 10, wherein the bonding pad is made of gold.

12. A method for manufacturing a substrate according to claim 10, wherein the bonding pad has a bonding-wire contact area two or more times larger than a contact area of a connection portion of a bonding wire.
